(19) United States
(12) Patent Application Publication
(10) Pub. No.: US 2002/0179830 A1
(43) Pub. Date: Dec. 5, 2002

(54) Halbach Dipole magnet shim system

(76) Inventors: Robert M. Pearson, Medford, OR (US); John G. Pearson, Medford, OR (US)

Correspondence Address: Andrew K. Youngs, 6723A 32nd Street, North Highlands, CA, 95660, US

(21) Appl. No.: 10/036,823

(22) Filed: Nov. 1, 2001

Related U.S. Application Data
(60) Provisional application No. 60/244,855, filed on Nov. 1, 2000.

(51) Int. Cl. G01R 23/02

(52) U.S. Cl. 250/250

(57) ABSTRACT

The geometry of a Halbach Dipole Array is ideal for use as a magnetic field source in a small nuclear magnetic resonance spectrometer, especially for spectrometers used for online process control. Use of Halbach Dipole Arrays as a magnetic field source for nmr spectroscopy has not previously been commercially feasible due to lack of economical processes or devices to improve the field homogeneity of these magnets, and the magnetic field of an unmodified Halbach Dipole Array is not sufficiently homogeneous to allow observation of a nuclear magnetic resonance signal.

This invention, comprising a process and the resulting assembly, allowing positioning of metal shims within the bore tube of a Halbach Dipole Array, improves the magnetic field homogeneity of said arrays sufficiently to allow routine observation of NMR signals in such fields, improving the utility of Halbach Dipole Arrays in NMR spectrometry and other applications. The process of shimming Halbach Dipole Arrays to achieve more homogenous fields is part of this invention.

### PRIORITY CLAIMS

The invention of this application claims priority under Disclosure Document 447230, incorporated by reference herein, and claims priority under U. S. provisional patent application number 60/244,855, incorporated by reference herein.

The geometry of a Halbach Dipole Array is ideal for use as a magnetic field source in a small nuclear magnetic resonance spectrometer, especially for spectrometers used for online process control. Use of Halbach Dipole Arrays as a magnetic field source for nmr spectroscopy has not previously been commercially feasible due to lack of economical processes or devices to improve the field homogeneity of these magnets, and the magnetic field of an unmodified Halbach Dipole Array is not sufficiently homogeneous to allow observation of a nuclear magnetic resonance signal.

This invention, comprising a process and the resulting assembly, allowing positioning of metal shims within the bore tube of a Halbach Dipole Array, improves the magnetic field homogeneity of said arrays sufficiently to allow routine observation of NMR signals in such fields, improving the utility of Halbach Dipole Arrays in NMR spectrometry and other applications. The process of shimming Halbach Dipole Arrays to achieve more homogenous fields is part of this invention.

### BACKGROUND OF THE INVENTION

Halbach Dipole Arrays and other condensed field magnets are described in detail by Sanker, Herbst, and Koon in “High Performance Permanent Magnet Materials”, Materials Research Society Symposia, Proceedings 96 (1987), incorporated by reference herein. In general these magnets are designed to focus the flow of magnetic flux across a desired open space and then return the flux through the body of the permanent magnet. In contrast, a standard H magnet uses a heavy and expensive steel yoke to provide a path for the returning flux. Hence, for a given field strength over similar sample volumes a Halbach Dipole Array will be lighter and less expensive than a standard H-type magnet, generally by at least a factor of two. Savings in both weight and cost are especially noticeable for applications requiring analysis of large samples, where use of a Halbach Dipole Array will lighten the instrument considerably and reduce the cost of constructing such an instrument. This makes the use of Halbach Dipole Arrays as magnetic field sources in NMR spectrometers used for analysis of larger samples, such as online process control, extremely desirable.

The Halbach Dipole Array was designed and first used as a focusing magnet in particle accelerators. As unmodified Halbach Dipole Arrays produce sufficiently homogeneous fields for use as particle accelerator refocusing magnets there was no need to improve the quality of the field for that application. While unmodified Halbach Dipole Arrays generally have more homogeneous fields than unmodified H magnets, the absence of any means of adjusting the field homogeneity of a Halbach Dipole Array, i.e. “shimming the magnet”, precludes its routine use in nmr spectroscopy or other applications requiring precise field homogeneity, for the field inhomogeneity of an unmodified Halbach Dipole Array is generally two to three orders of magnitude too great for observation of an nmr signal.

Use of unmodified Halbach Dipole Arrays is taught and claimed by Merritt, et. al. (U.S. Pat. No. 5,705,902) as a magnetic source for direct current motors and generators. Schlueter, et. al., (U.S. Pat. No. 5,099,175) discusses the use of dipole arrays in wiggler technology. In these devices the unmodified array has sufficient magnetic homogeneity to be efficient, and reducing field inhomogeneity is not an object.

Sasaki, et. al. (U.S. Pat. No. 5,565,747) describes and claims a magnetic field generator which utilizes four horizontal magnets to approximate a linear field for an insertion device. Sasaki does not achieve the low levels of field inhomogeneity necessary for nuclear magnetic resonance spectrometry.

This invention comprises a device and process to improve the field homogeneity of Halbach Dipole Arrays such that they may be used as magnetic field sources for applications requiring precise field homogeneity, including nuclear magnetic resonance spectrometers. The principle of nuclear magnetic resonance (nmr) and the operation of nmr spectrometers is described in numerous texts, one of the more accessible of which is “Pulse and Fourier Transform nmr; Introduction to practice and theory” by Farrar and Becker, Academic Press, New York, 1971.

NMR spectrometers may be divided into two broad groups of instruments, continuous wave (cw) spectrometers and pulsed spectrometers. NMR signals are excited in materials when the resonance condition of the desired nuclei are meet. This involves placing the material in a strong magnetic field and exposing it to radio waves of the appropriate frequency. A continuous wave (cw) spectrometer accomplishes this by holding one of the two constant, generally a weak radio frequency source, and sweeping the other, generally the magnetic field, across a range containing the resonance condition. A pulsed spectrometer accomplishes this by holding the magnetic field constant and briefly pulsing a strong radio frequency source. Currently pulsed spectrometers are the more common device, but both types of NMR spectrometer require magnets capable of producing strong and homogeneous magnetic fields over an accessible sample volume.

The shim system and process described here has been tested with and found to improve magnetic field homogeneity in both a 2.6 inch and a 5.5 inch free-bore Halbach Dipole Array, but it is to be understood that this system may be applied to Halbach Dipole Arrays of essentially any size. The device and process is referred to as a shim system, for it improves the field homogeneity of the Halbach Dipole Array by the addition of steel shim stock (shims) into the central free space of the Array, otherwise referred to as the magnet bore. The purpose of these metal shims is to alter the magnetic field such that variations in the field are reduced and a more uniform field exists in the region of the magnet bore occupied by the material under NMR analysis, the sample. Further adjustment of magnetic fields homogenized via the passive shimming of Halbach Dipole Arrays may be accomplished, and these assemblies and processes are part of this invention.

Several techniques exist for either improving magnetic field homogeneity or removing the effects of inhomogeneity, for arbitrarily uniform magnetic fields have been desired since at least the discovery of nmr in 1946 and no magnet produces such a field. All these techniques have limitations and it is generally necessary to use two or more at once to obtain the desired effect. As minimal desired magnetic field inhomogeneity and sample handling requirements vary widely between applications, any combination of the following techniques may be used.

It is possible to correct magnetic field variations in a range of magnet types with the addition of either metal shims or small electromagnet arrays in certain prescribed geometric orientations. Metal shims are generally made of steel and referred to as passive shims, while electromagnet arrays (also know as electric shims) are referred to as active shims. It is common practice to add either or both passive and active shims to conventional magnets used in NMR spectrometers, whether the system uses a permanent, superconducting, or electromagnet. Sullivan (U.S. Pat. No. 3,223,897) discloses and claims the passive shimming of a standard H-type electromagnet fitted with soft steel pole pieces is given by Sullivan in U.S. Pat. No. 3,223,897. Passive shims are limited by considerations and cost of precise machining, while active shims are limited by the amount of current needed to produce large corrections. Hence, one generally uses passive shims at first then adds active shims if finer correction is desired. It is also common practice to reduce the effects of magnetic field inhomogeneity by spinning the sample about an axis perpendicular to the magnetic field lines of force, for in a rotating sample the effective magnetic field at each nuclei is the average field experienced by the nuclei during rotation and this averaging reduces the effects of non-uniform magnetic fields. Sample spinning is limited by spinning speed, for reaching the speed of sound is a catastrophic event for the sample and this may be easily done with air-driven spinners. Also, not all materials or applications are amenable to sample spinning, such as a material of uneven density or an application requiring automated sampling of a product stream. As such, sample spinning is most commonly used on liquid samples in laboratory situations. Another widely used method of removing the effect of non-uniform magnetic fields is by subjecting the sample to trains of radio frequency (rf) pulses, such as in a Carr-Purcell-Mibloom-Gill (CPMG) experiment. This method works because the effect of non-uniform magnetic field upon the sample is signed with respect to the sample coil, that is, it is possible to use RF pulses to invert the effect and watch it regress back to zero. The drawbacks of RF methods are related to the speed at which one can pulse and whether elimination of certain types of information (e.g. the chemical shift) in the observed signal is acceptable.

Gluckstem, et. al., (U.S. Pat. No. 4,580,098) and Beer (U.S. Pat. No. 4,703,276) both teach segmented magnet arrays for use in nuclear magnetic resonance to achieve sufficient field uniformity. In both cases the procedure involves building the magnetic array and tuning it via its own geometry rather than shimming. Achieving field homogeneity via this method would be a more expensive and time-consuming method than the current invention, and unlikely to achieve the low levels of field inhomogeneity achieved by the current invention.

Battocletti, et. al., (U.S. Pat. No. 4,613,818) teaches the use of coarse adjustment of magnetic fields in nmr used for blood flow analysis by the use of mechanical shims of the polarizing magnets, and further teaches the use of Hall effect sensors in conjunction with such shims. Battoclettis goes on, though, to describe the undesirable flux variations achieved with this system, especially under temperature variation. The current invention provides a finer adjustment capability as well as temperature control, neither of which were obvious over the teachings of Battoclettis.

The current invention comprises the application of passive shimming techniques to the Halbach Dipole Array configuration of magnetic material. Since such techniques are generally used in conjunction with other methods outlined above, thus the use of the invention by itself or in conjunction with any particular set of complimentary devices or techniques shall not be construed as a limitation.

### BRIEF SUMMARY OF THE INVENTION

A passive shim system is provided for reduction of magnetic field inhomogeneity in the central free space of a Halbach Dipole Array. This is accomplished by the precise placement of multiple strips of mild steel shim stock both along the axis of the cylindrical free space and in rings about this space. Magnetic field inhomogeneity is evaluated by both mapping the free space with a Hall probe and by observation of an NMR signal free induction decay. Both techniques for evaluating field homogeneity are well known to those with average skill in the field of magnets and magnetic field adjustment. Coarse adjustments are achieved by varying thickness and length of the steel shims. Fine adjustments are achieved by precise variation of the shim position with respect to the Halbach Dipole Array, laterally along the axis of, radially within, and angularly along the circumference of the cylindrical free space. The level of acceptable magnetic field inhomogeneity is application dependent and varies widely. This invention has been used to decrease magnetic field inhomogeneity by multiple orders of magnitude in Halbach Dipole Arrays of different sizes and field strengths.

### BRIEF DESCRIPTION OF THE FIGURES

The foregoing objects, features and advantages of the present invention will be more clearly understood from consideration of the following detailed description thereof, taken in conjunction with two Figures, which schematically show a system for reducing magnetic field inhomogeneity in a Halbach Dipole Array and give detailed depiction of a central element of the device, a single steel shim positioning assembly.

FIG. 1 depicts one preferred embodiment of the entire apparatus as used to shim a temperature controlled Halbach Dipole Array for use in an NMR spectrometer. FIG. 2 depicts a single lateral shim positioning assembly.

### DETAILED DESCRIPTION OF THE INVENTION

To aid in description of the invention, reference is made to example working models constructed for use with specific Halbach Dipole Arrays as magnetic field sources for NMR spectrometers. It is understood that this invention may be applied to Halbach Dipole Arrays of any size and for any application in which a reduction of field inhomogeneity is desired, and that examples of specific systems shall not be construed as limiting the scope of application.

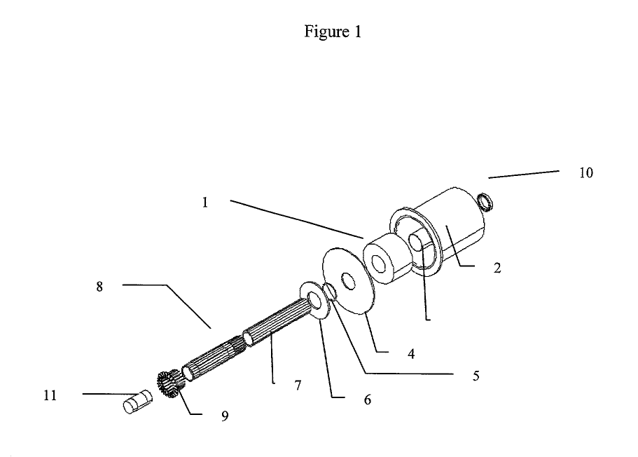

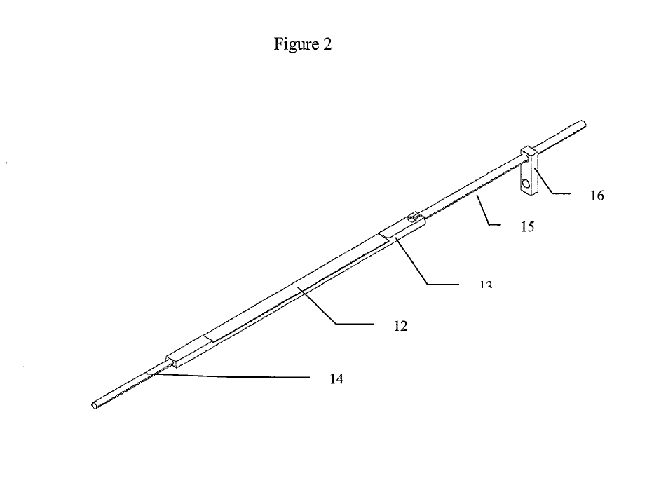

FIG. 1 depicts one preferred embodiment of the entire apparatus as used to shim a temperature controlled Halbach Dipole Array for use in an NMR spectrometer. FIG. 2 depicts a single lateral shim positioning assembly.

FIG. 1 is an exploded drawing of one preferred embodiment of the invention as installed in a temperature-controlled Halbach Dipole Array. Halbach Dipole Array 1 is utilized within the invention as delivered from the manufacturer within its standard configuration. Items 2, 3, 4, 5 and 6 are part of a fluid bath temperature control system for the magnet, to prevent drift in the magnetic field with change in ambient temperature. Item 2 is the temperature control vessel, item 3 is the bore tube, item 4 is the top plate, item 5 is an o-ring, and item 6 is the upper sealing ring. When assembled, the upper edge of the bore tube 3 is even with the upper surface of the sealing ring 6. The invention is mounted to the temperature control vessel 2 containing the magnet 1 with both being included in FIG. 1 to provide context for the invention. The invention itself places lateral steel shims 12 in the cylindrical free space of a Halbach Dipole Array 1 in the pattern of an n-sided polygon and radial steel shims 11 in cylinders about the central region of the free space of said array 1. The n lateral shims 12 are affixed, most often by adhesive bonding, to an array of n shim holders 8, most often made from brass. The shims holders 8 are inserted between the bore tube 3 of the temperature control system and an n-faced polygonal aluminum tube 7. Lifter rods 15 in the shim lifter array 9 are snap-fitted to the top of the shim holders 8, and the tabs 16, most often made of brass, in the lifter array 9 are fastened, most often by bolting, to the upper sealing ring 6 of the temperature control vessel, which also serves as a retaining ring. Retaining pins 14 from the bottom of the shim holders 8 extend through holes in a lower retaining ring 10, affixed, most often by welding, to the bottom of the temperature control vessel 2. The radial shim array 11 is affixed to the exterior surface of an NMR probe before the probe is inserted into the polygonal tube 7. In another embodiment, the radial shim array 11 may be affixed to the interior surface of the lateral shim array 8, normally with the use of a non-conductive, non-magnetic spacer cylinder.

The shim arrays are scaled to a size appropriate for each Halbach Dipole Array, the size of which vary greatly between applications. Successful experiments have included systems containing 8 and 20 lateral shims in the two systems used to reduce magnetic field inhomogeneity in both a 2.6″ and a 5.5″ Halbach Dipole Array. However, based on the application particulars, the number of lateral shims may be varied more widely. For a system of 20 shims designed for a 0.25 Tesla Halbach Dipole Array with a 70 mm diameter cylindrical free space the steel shims utilized varied in length from 50 mm to 150 mm, were up to 0.77 mm thick, and were held on shim holders 216 mm long. The radial shims were up to 50 mm wide and 0.1 mm thick.

FIG. 2 is a drawing of a single lateral steel shim positioning assembly rotated 180 degrees with respect to FIG. 1. A strip of shim stock 12, most often made from mild steel, is affixed to a shim holder 13, most often made from brass. Each shim holder 13 is affixed, most often by soldering, to a rigid retaining pin 3 at the base. Each shim holder 13 has a T-shaped notch at the top for insertion of a detachable lifting rod 15, most often made of brass. The main body of each lifting rod 15 may be threaded, and passes through a matching threaded hole in a brass tab 16, most often made from brass, mounted to the retaining ring 6 affixed to the top of the temperature control vessel 2. Other means for affixing tab 16 to rod 15 may be employed. Individual shim holders 13 are separated from one another by spacers made of a non-magnetic, non-conductive material, most often rectangular pieces of delrin acetal sheet. When fully assembled the shim holders 13 form an n-sided polygon 8 within the magnet bore, and the brass tabs form an segmented ring 9 held to the top of the temperature control vessel 2.

It is understood that a wide range of alternate materials may be used for various components of the invention. The shim strips 12 interact with and alter the magnetic field of Halbach Dipole Array 1, so shim strips 12 may be made out of any material with an appreciable magnetic susceptibility. Mild steel was utilized in the preferred embodiment, but various other steels, iron, cobalt, nickel, other alloys of these metals, or any other magnetically susceptible material may be used. The remainder of the components are best manufactured from materials without appreciable magnetic susceptibility. The illustrated embodiment utilized brass, aluminum, and delrin, but materials such as Teflon, ceramics, copper, wood, glass, plastics or any other material without appreciable magnetic susceptibility may be used.

The invention allows steel shims 12 to be easily inserted and removed from the magnet 1. This allows the operator to vary shim thickness and geometry by removing individual shims on their holders and replacing them with another. The shim holder 13 is held in a vertical line by a lifting rod 15 on top and a retaining pin 14 below, each end passing through a retaining ring 6 at the top and 10 at the bottom. The shim holder 13 is constrained from rotating about this axis by being sandwiched between the aluminum polygonal tube 7 and the bore tube 3. The lifting rods 15 allow for precise positioning of the shims along the axis of the bore of the magnet 1, made particularly efficient in the threaded embodiment. Radial position of the shims 12 may also be varied by using shim holders 13 of differing thickness of the central notched region. Finally, small adjustments of the angular position of the shims 12 are made by varying the thickness of the delrin spacers placed between each adjacent shim 12. Magnetic field inhomogeneity is reduced by finding optimal values for shim thickness, shim geometry, lateral position, radial position, and angular position for all n shims in the array. Magnetic field inhomogeneity may be monitored by mapping the magnet bore with a Hall probe or any other device capable of measuring magnetic field strength, such as a superconducting quantum interference device (SQUID), or by observation of the nmr signal of a proton bearing liquid, such as acetone, if the field variation is less than a few gauss. Operationally it is easiest to monitor the field inhomogeneity by observation of an NMR signal, but an NMR spectrometer is not required for use of the invention.

### EXAMPLE

A 70 mm free bore Halbach Dipole Array with a magnetic field of 0.25 Tesla was purchased for use in NMR analysis of viscous industrial liquids and mixes. The Halbach Dipole Array is made of wedges composed of microcrystalline Nd—Fe—B compound arranged in rings stacked into a cylinder. Magnetic fields produced by Nd—Fe—B materials are highly temperature dependent, so the Halbach Dipole Array was placed in a circulating fluid temperature control vessel and maintained at 35 degrees Centigrade. The magnetic field across a 30 mm diameter and 3 mm thick disc perpendicular to the cylindrical axis and in the center of the bore was mapped using a Hall probe mounted to an x-y-z stepper motor. The field was found to vary by approximately 0.0025 Tesla (25 Gauss) over this volume, which is approximately a factor of 50 greater than the allowable magnetic field homogeneity for the application.

A set of 20 shim positioning arrays was constructed, with parts fabricated from commercially available shim, bar, and pipe stock. Mild steel shims of uniform thickness (0.020″) and geometry (rectangular, 0.30″ by 6.0″) were affixed to the shim holders with cyanoacrylate adhesive. The invention was assembled by inserting the 20-sided polygonal tube into the bore, followed by guiding individual shim assemblies between the faces of the polygonal tube and the inner surface of the temperature controller bore tube. Lower retaining pins were guided through the lower retaining ring, Delrin spacers of uniform thickness (0.010″) were placed between shim holders, all the lifter rods were adjusted to the midpoint of their range, and all the lifter rods were fixed in position by bolting the threaded brass tabs to the temperature control vessel upper sealing ring. This centered the mild steel shims with respect to the midpoint of the Halbach Dipole Array free space and prevented uncontrolled movement of the shims.

Mapping of the magnetic field by use of a Hall probe was repeated. The field was found to vary by about 0.0002 Tesla (2 Gauss) over the mapped volume. As this is homogeneous enough to observe an NMR signal an NMR probe was inserted with a 25 mm wide sample of canola oil and a fast dephasing NMR signal was observed. The probe was withdrawn and a radial shim of 0.001″ thickness and 1.5″ width was affixed to the probe with tape. The NMR signal was seen to dephase more slowly (i.e. the free induction decay was longer), the probe was withdrawn and the radial shim was replaced with a similar strip of shim stock 0.002″ thick. The process was repeated until the free induction decay was observed to be longest, indicating the lowest magnetic field inhomogeneity as a function of radial shim used.

The lateral shims were adjusted in successive steps. First, a shim was replaced with a slightly thinner shim (0.018″) and the free induction decay was inspected for evidence of lower or higher magnetic field inhomogeneity. If the free induction decay lengthened, the shim was again replaced with yet a thinner shim. If the free induction decay shortened the shim was replaced with a thicker shim. Using commercially available shim stock, shim thickness is adjustable to within 0.001″. Each shim thickness was adjusted until the free induction decay was observed to be the longest, indicating the lowest level of magnetic field inhomogeneity. Shim thickness was adjusted in a pattern of opposing shim holders, to keep the most homogeneous region of the magnetic field in the center of the bore tube, i.e. after optimizing shim thickness in position 1 of 20, position 11 was optimized, then 2, then 12, etc. This process continued through the 20 positions until no further improvement could be made, which was twice about the circuit.

Once the optimal thicknesses were determined, the position of each shim along the axis of the bore tube was adjusted. This was done by soldering hex nuts to the top of each threaded lifting rod and using a socket wrench to turn the lifting rod. Each revolution of the rod translates the mild steel shim 1/32^{nd} of an inch either direction along the bore tube, and could move up to one inch away from center for a total range of 64 turns per shim. Again, length of free induction decay was used to monitor the magnetic field inhomogeneity and shims lifter rods were adjusted on opposing positions, i.e., 1 to 11, 2 to 12, etc.

The length of mild steel shims on shim holders was adjusted at or near the limits of the lifter rod range of motion. One, two, three, and four inch strips of mild steel shim stock were used to replace the six inch originals, and the free induction decay was inspected for effects on magnetic field inhomogeneity. The thickness of these shorter shims was also varied, with the optimal thickness of a shorter shim generally being greater than a longer shim. Varying the length of a mild steel shim allows the user to place of the lower and upper edges of the shim and the center of the shim at a wider range of locations and did visibly lengthen the free induction decay.

An investigation was conducted using three inch shims uniformly about the bore tube and found the resulting best magnetic field to be more inhomogeneous than that produced with the same system containing a mixture of shim lengths. Also investigated was placement of two inch strips of mild steel shim stock on top of the original six inch strips of mild steel shim stock, creating shims thicker in the middle than on the ends, and again found the resulting best magnetic field to be more inhomogeneous that a mixture of short and long shims of single strips.

Radial position of the lateral shims was adjusted by varying the thickness of the central portion of the brass shim holders in steps of 0.010″. This was done by making several extra shim holders of with the central region milled to be 0.010″ and 0.020″ thicker than the initial holders, affixing mild steel shims identical to those already in place, and then swapping the shims and holders with those already in place. Again, length of the free induction decay was used to monitor the magnetic field inhomogeneity and shim holder thickness was adjusted on opposing positions, i.e. 1 to 11, 2 to 12, etc.

Lateral shim positions were further adjusted by varying the thickness of Delrin spacers between the shim holders. While the range of motion available was very limited this adjustment did noticeably alter the length of the free induction decay. Again, length of the free induction decay was used to monitor the magnetic field inhomogeneity.

At this point the magnetic field inhomogeneity was low enough to allow use of the Halbach Dipole Array as a magnetic field source for the desired application. Using a version of the invention containing 20 shim-positioning assemblies, the magnetic field inhomogeneity of a commercially available Halbach Dipole array had been reduced by ninety-nine percent. Further adjustments of the steel shim geometry, such as varying the width from 0.30″ or by placing multiple short shims of varying thickness and width on each holder, were not necessary for the desired application but are obvious extensions of the above method.

We claim:

1. A system for reducing the inhomogeneity of the magnetic fields of Halbach Dipole Arrays comprising a set of mechanical shims positioned within a Halbach Dipole Array;
said shims being of varying width, thickness, geometry and length;
said shims being made of material with appreciable magnetic susceptibility;
with means for said shims to be mounted to be placed and precisely positioned within the Halbach Dipole Array.

2. The system of claim 1 wherein the shims include both lateral and radial shims.

3. The system of claim 1 which uses electromagnetic arrays to provide additional adjustment of magnetic fields.

4. The system of claim 1 which uses sample spinning techniques to provide additional averaging of magnetic field effects.

5. The system of claim 1 which uses radio frequency pulse techniques to provide additional averaging of magnetic field effects.

6. The system of claim 1 which uses a temperature control fluid to stabilize the magnetic field strength within a Halbach Dipole Array.

7. A process for reducing the inhomogeneity of the magnetic fields produced by Halbach Dipole Arrays comprising the placement of a set of mechanical shims within the Halbach Dipole Array;
said shims being of varying width, thickness, geometry and length;
said shims being made of material with appreciable magnetic susceptibility;
with means for said shims to be mounted to be placed and precisely positioned within the Halbach Dipole Array.

8. The process of claim 7 which uses a Hall probe to monitor magnetic field strength at a variety of locations within the Halbach Dipole Array as means of evaluating magnetic field homogeneity.

9. The process of claim 7 which uses a nuclear magnetic resonance spectrometer, either pulsed or continuous wave, to evaluate magnetic field homogeneity.

10. The process of claim 7 which uses a superconducting quantum interference device (SQUID) to evaluate magnetic field homogeneity.

11. The process of claim 7, further comprising the application of an active shimming process to improve field homogeneity.

12. The process of claim 11, wherein the active shimming process comprises the use of electromagnetic arrays to provide additional adjustment of magnetic fields.

13. The process of claim 11, wherein the active shimming process comprises utilizing sample spinning techniques to provide additional averaging of magnetic field effects.

14. The process of claim 11, wherein the active shimming process comprises utilizing radio frequency pulse techniques to provide additional averaging of magnetic field effects.

15. The process of claim 11, wherein the active shimming process comprises utilizing a temperature control fluid to stabilize the magnetic field strength within the Halbach Dipole Array.

16. A nuclear magnetic resonance device utilizing a magnetic field source comprising a mechanically shimmed Halbach dipole array.
